(19) United States
(12) Patent Application Publication
(10) Pub. No.: US 2026/0354030 A1
(43) Pub. Date: Nov. 5, 2026

(54) PIEZOELECTRIC SINGLE CRYSTAL ELEMENT

(71) Applicant: IBULE PHOTONICS INC., Incheon (KR)

(72) Inventors: Sang-Goo LEE, Incheon (KR); Myungjoo KWON, Incheon (KR); Yoonsang JEONG, Incheon (KR)

(73) Assignee: IBULE PHOTONICS INC., Incheon (KR)

(21) Appl. No.: 19/545,418

(22) Filed: Feb. 20, 2026

(30) Foreign Application Priority Data
Feb. 24, 2025 (KR) 10-2025-0023833

(51) Int. Cl. H10N 30/853; H10N 30/30; H10N 30/85

(52) U.S. Cl. CPC H10N 30/8548; H10N 30/852; H10N 30/302

(57) ABSTRACT

A piezoelectric single crystal element according to an aspect of the present invention is a piezoelectric single crystal element including one or more piezoelectric single crystals, in which the one or more piezoelectric single crystals include a solid solution with a chemical formula yPb(In_{1/2}Nb_{1/2})O₃-xPbTiO₃—(1−x−y)Pb(Mg_{1/3}Nb_{2/3})O₃, wherein x is greater than 0 to 0.54 or greater than 0 to 0.5, and y is greater than 0 to 0.4 or greater than 0 to 0.3, and manganese (Mn) doped into the solid solution at a concentration of 0.45 to 0.55 mol %, 0.65 to 0.75 mol %, 1.45 to 1.55 mol %, or 1.75 to 1.85 mol %, and have a piezoelectric strain constant (d₃₃) of 1150 to 1470 pC/N.

### CROSS-REFERENCE TO RELATED APPLICATION

This application claims priority to and the benefit of Korean Patent Application No. 10-2025-0023833, filed on Feb. 24, 2025, the disclosure of which is incorporated herein by reference in its entirety.

### BACKGROUND

### 1. Field of the Invention

The present invention relates to a piezoelectric single crystal element.

### 2. Discussion of Related Art

As single crystal dielectrics that exhibit good piezoelectric properties compared to lead zirconate titanate (PZT) ceramics, one of the representative existing dielectrics, have been commercialized, single crystal dielectrics are being widely used as piezoelectric materials in various fields such as industry, medicine, and defense. As piezoelectric single crystals used as single crystal dielectric materials, the first-generation single crystal PMN-PTPb(Mg_{2/3}Nb_{1/3})O₃—PbTiO₃], the second-generation single crystal PIN-PMN-PT [Pb(In_{1/2}Nb_{1/2}O₃)—Pb(Mg_{1/3}Nb_{2/3}O₃)—PbTiO₃], and the third-generation single crystal Mn:PIN-PMN-PT, which is obtained by adding dopants such as Mn to the first and second-generation single crystals, are widely used.

Examples of devices utilizing the piezoelectric single crystal include i) sensor devices, such as ultrasonic sensors, infrared sensors, shock detection sensors, acceleration sensors, gyro sensors, and LiDAR sensors for autonomous driving, which are applied to vehicles and other industrial devices as industrial dielectric devices, resonators, microphones, speakers, energy harvesting devices, quantum computer devices, logic operation devices applied to non-volatile memories, and actuators, ii) wearable healthcare devices (e.g., vibration sensors), which detect the bio-signals of users (e.g., heart rates) as medical dielectric devices and ultrasound probes, and iii) sonar systems and underwater acoustic sensors as military dielectric devices.

The background art of the present invention is disclosed in Korean Laid-Open Patent No. 10-2020-0017193 (published on Feb. 18, 2020).

### SUMMARY OF THE INVENTION

The present invention is directed to providing a piezoelectric single crystal element capable of improving the energy density and energy conversion efficiency of various dielectric devices (e.g., energy harvesting devices) utilizing the piezoelectric single crystal.

However, the technical problems to be solved by the present invention are not limited to the above-described problem, and other problems that are not mentioned can be clearly understood by those skilled in the art from the following description of the present invention.

A piezoelectric single crystal element according to an aspect of the present invention is a piezoelectric single crystal element including one or more piezoelectric single crystals, wherein the one or more piezoelectric single crystals include a solid solution with a chemical formula yPb(In_{1/2}Nb_{1/2})O₃-xPbTiO₃-(1−x−y)Pb(Mg_{1/3}Nb_{2/3})O₃, wherein x is greater than 0 to 0.54 or greater than 0 to 0.5, and y is greater than 0 to 0.4 or greater than 0 to 0.3, and manganese (Mn) doped into the solid solution at a concentration of 0.45 to 0.55 mol %, 0.65 to 0.75 mol %, 1.45 to 1.55 mol %, or 1.75 to 1.85 mol %, and have a piezoelectric strain constant (d₃₃) of 1150 to 1470 pC/N.

A figure of merit (FoM) of the piezoelectric single crystals may have a peak in a Mn doping concentration range of 0.45 to 0.55 mol %, 0.65 to 0.75 mol %, 1.45 to 1.55 mol %, or 1.75 to 1.85 mol %.

A first FoM of the piezoelectric single crystals, which is defined according to a piezoelectric strain constant (d₃₃) and a piezoelectric voltage constant (g₃₃) of the piezoelectric single crystal, may have a peak in a Mn doping concentration range of 0.45 to 0.55 mol %, 0.65 to 0.75 mol %, or 1.45 to 1.55 mol %.

The peak of the first FoM may have a value between 50 and 56 pm²/N, a value between 52 and 54 pm²/N, or a value between 50 and 65 pm²/N in the Mn doping concentration range of 0.45 to 0.55 mol %, 0.65 to 0.75 mol %, or 1.45 to 1.55 mol %.

A second FoM of the piezoelectric single crystals, which is defined according to the electromechanical coupling factor (k₃₃) and a mechanical quality factor (Qₘ) of the piezoelectric single crystals, may a peak in a Mn doping concentration range of 1.75 to 1.85 mol %.

The peak of the second FoM may have a value between 363 and 367 in the Mn doping concentration range of 1.75 to 1.85 mol %.

A crystal orientation of the piezoelectric single crystal may be a <011> axis.

The piezoelectric single crystals may be provided as a plurality of piezoelectric single crystals, polymer layers may be disposed between the piezoelectric single crystals such that the piezoelectric single crystal element may constitute a piezoelectric single crystal composite, and the polymer layers may have an arrangement structure that attenuates a negative piezoelectric strain constant corresponding to an arrangement direction thereof or define a vibration mode (extension mode) of each piezoelectric single crystal.

### BRIEF DESCRIPTION OF THE DRAWINGS

The following drawings attached to the present specification illustrate exemplary embodiments of the present invention and serve to further assist understanding of the technical idea of the present invention together with the detailed description of the present invention, which will be described below, so the present invention should not be construed as being limited to the details shown in the accompanying drawings, in which:

FIG. 1 is an exemplary diagram of an energy harvesting device to which a piezoelectric single crystal is applied;

FIG. 2 shows experimental data showing a relationship between a manganese doping concentration and a piezoelectric strain constant (d₃₃);

FIG. 3 shows experimental data showing a relationship between the manganese doping concentration and a piezoelectric voltage constant (g₃₃);

FIG. 4 shows experimental data showing a relationship between the manganese doping concentration and an electromechanical coupling factor (k₃₃);

FIG. 5 shows experimental data showing a relationship between the manganese doping concentration and a mechanical quality factor (Qₘ);

FIG. 6 shows experimental data showing a relationship between the manganese doping concentration and first figure of merit (FoM);

FIG. 7 shows experimental data showing a relationship between the manganese doping concentration and a second FoM;

FIG. 8 shows experimental data showing a relationship between the manganese doping concentration and a third FoM;

FIG. 9 is an exemplary diagram illustrating a relationship between a crystal orientation of the piezoelectric single crystal and the piezoelectric strain constant;

FIG. 10 is an exemplary diagram of a piezoelectric single crystal element implemented as a 2-2 composite; and

FIG. 11 is an exemplary diagram illustrating a vibration mode of a piezoelectric single crystal element implemented as a 1-3 composite.

### DETAILED DESCRIPTION OF EXEMPLARY EMBODIMENTS

Hereinafter, exemplary embodiments of the present invention will be described in detail.

However, the following is merely a detailed description of specific embodiments, and the present invention may be modified in various ways and may take various forms, and therefore the present invention is not limited to the illustrated specific embodiments. The present invention should be construed to include all modifications, equivalents, or substituents falling within the spirit and technical scope of the present invention.

In addition, in the following description, many specific items such as specific components are described, these specific items are only provided to help better understand the present invention, and it will be apparent to those skilled in the art that the present invention may be practiced without these specific items. In addition, in the following description of the present invention, when a detailed description of a known function or related art is determined to unnecessarily obscure the gist of the present invention, the detailed description thereof will be omitted herein.

In addition, terms used herein are used to describe only specific embodiments and are not intended to limit the present invention. Unless otherwise defined, all terms including technical or scientific terms used herein have the same meaning as commonly understood by those skilled in the art to which the present invention pertains. General terms that are defined in a dictionary should be construed as having meanings that are consistent in the context of the relevant art and are not to be interpreted in an idealized or overly formal sense unless clearly defined in the present application.

In the present application, the singular forms include plural forms unless the context clearly notes otherwise.

In the present application, although terms “first,” “second,” and the like may be used herein to describe various components, it should be understood that these components are limited by these terms. The terms are used only for the purpose of distinguishing one component from another component. For example, without departing from the scope of the present invention, a first component may be referred to as a second component, and similarly, a second component may also be referred to as a first component.

In the present application, a term such as “include,” “contain,” or “have” is intended to indicate the presence of features and components (or constituents) described in the specification, but does not mean that one or more other features or components is not present or cannot be added.

A piezoelectric single crystal element described in the present embodiment can be defined as a structure including one or more piezoelectric single crystals. When the piezoelectric single crystal element includes only one piezoelectric single crystal, the piezoelectric single crystal itself may constitute the piezoelectric single crystal element of the present embodiment, and when the piezoelectric single crystal element includes a plurality of piezoelectric single crystals, a piezoelectric single crystal composite including a plurality of piezoelectric single crystals and a polymer layer disposed between the piezoelectric single crystals may constitute the piezoelectric single crystal element of the present embodiment.

The piezoelectric single crystal may be implemented as a third-generation single crystal Mn:PIN-PMN-PT, which includes a solid solution with a chemical formula yPb(In_{1/2}Nb_{1/2})O₃-xPbTiO₃-(1−x−y)Pb(Mg_{1/3}Nb_{2/3})O₃, wherein x is greater than 0 to 0.54 or greater than 0 to 0.5, and y is greater than 0 to 0.4 or greater than 0 to 0.3, and manganese (Mn) doped into the solid solution at a concentration in a predetermined range. A crystal orientation (polarization direction) of the piezoelectric single crystal may be a <011> axis. The piezoelectric single crystal may be manufactured from an ingot obtained by putting a ceramic powder in a platinum crucible loaded with seeds with a crystal growth orientation (<011> axis), sealing the platinum crucible, placing the platinum crucible in a high-temperature crystal growth furnace for a long time to completely melt the ceramic powder, maintaining the temperature for a predetermined period of time, and then slowly cooling the ceramic powder.

The present embodiment presents a piezoelectric single crystal element that can improve the energy density and energy conversion efficiency of various dielectric devices. Examples of various dielectric devices utilizing the piezoelectric single crystal include i) sensor devices, such as ultrasonic sensors, infrared sensors, shock detection sensors, acceleration sensors, gyro sensors, and LiDAR sensors for autonomous driving, which are applied to vehicles and other industrial devices as industrial dielectric devices, resonators, microphones, speakers, energy harvesting devices, quantum computer devices, logic operation devices applied to non-volatile memories, and actuators, ii) wearable healthcare devices (e.g., vibration sensors), which detect bio-signals of users (e.g., heart rates) as medical dielectric devices and ultrasound probes, and iii) sonar systems and underwater acoustic sensors as military dielectric devices. In order to help understand the present embodiment, an example in which the piezoelectric single crystal element of the present embodiment is applied to an energy harvesting device will be described below.

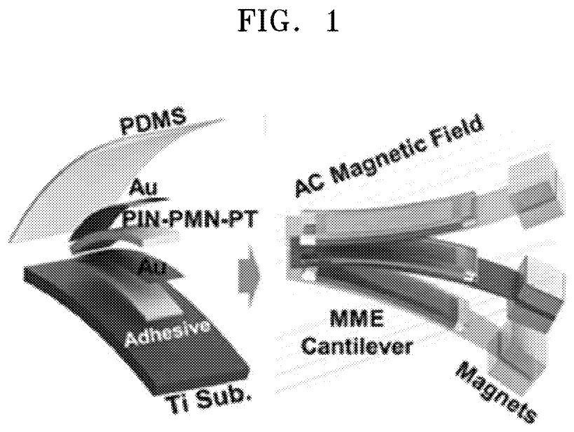

FIG. 1 shows an example of a cantilever-type energy harvesting device to which the piezoelectric single crystal element is applied. The energy harvesting device of FIG. 1 has a magneto-mechano-electric (MME) conversion mechanism in which a cantilever is displaced when an AC magnetic field is applied to a magnet serving as a head mass, and power is generated by the displacement.

The energy density of the energy harvesting device under non-resonant conditions is expressed as in the following Expression 1.

$$U = \frac{1}{2} ( {d}_{ij} \cdot {g}_{ij} ) {( \frac{F}{A} )}^{2} \qquad [ Expression 1 ]$$

In Expression 1, dᵢⱼ indicates a piezoelectric strain constant, gᵢⱼ indicates a piezoelectric voltage constant, F indicates a force applied to the energy harvesting device, and A indicates an area to which the force is applied. Among the terms of Expression 1, “dᵢⱼ·gᵢⱼ” corresponds to a figure of merit (FoM) (FoM_{res_off}) (hereinafter referred to as a first FoM) of a piezoelectric single crystal, which defines the energy density of the energy harvesting device under non-resonant conditions.

The energy conversion efficiency of the energy harvesting device under resonant conditions is proportional to an electromechanical coupling factor and a mechanical quality factor of the piezoelectric single crystal, as in the following Expression 2.

$$Efficiency ∝ {k}_{ij}^{2} \cdot {Q}_{m} \qquad [ Expression 2 ]$$

In Expression 2, kᵢⱼ indicates the electromechanical coupling factor and Qₘ indicates the mechanical quality factor. In Expression 2,

$$“ {k}_{ij}^{2} \cdot {Q}_{m} ”$$

corresponds to an FoM (FoM_{res_on}) (hereinafter referred to as a second FoM) of the piezoelectric single crystal, which defines the energy conversion efficiency of the energy harvesting device under resonant conditions.

In addition, an FoM indicating energy density and energy conversion efficiency encompassing both non-resonant conditions and resonant conditions is defined as a third FoM, and the third FoM may be defined as the product of the first and second FoMs (i.e., the third

$$FoM = {d}_{ij} \cdot {g}_{ij} \cdot {k}_{ij}^{2} \cdot {Q}_{m} ) .$$

The present embodiment presents the properties of the piezoelectric single crystal for maximizing energy density and energy conversion efficiency by ensuring that the first and second FoMs have peaks under the non-resonant and resonant conditions described above.

To this end, Mn doped at a predetermined concentration may be additionally included in the solid solution to constitute the piezoelectric single crystal. A Mn doping concentration range may be (range 1) 0.45 to 0.55 mol %, (range 2) 0.65 to 0.75 mol %, (range 3) 1.45 to 1.55 mol %, or (range 4) 1.75 to 1.85 mol %. In each Mn doping concentration range among ranges 1 to 4, the FoM of the piezoelectric single crystal may have a local peak (local maximum).

In particular, the first FoM of the piezoelectric single crystal defined according to the piezoelectric strain constant d₃₃ and the piezoelectric voltage constant g₃₃ of the piezoelectric single crystal may have a peak in each Mn doping concentration range of (range 1) 0.45 to 0.55 mol %, (range 2) 0.65 to 0.75 mol %, and (range 3) 1.45 to 1.55 mol %. The first FoM is defined as d₃₃-g₃₃.

In this case, a peak of the first FoM may have a value between 50 and 56 pm²/N, a value between 52 and 54 pm²/N, and a value between 50 and 65 pm²/N in each manganese doping concentration range of ranges 1 to 3.

In addition, the second FoM of the piezoelectric single crystal, which is defined by the electromechanical coupling factor k₃₃ and the mechanical quality factor Qₘ of the piezoelectric single crystal, may have a peak in the Mn doping concentration range of (range 4) 1.75 to 1.85 mol %. The second FoM is defined as k₃₃·Qₘ.

In this case, a peak of the second FoM may have a value between 363 and 367 in the Mn doping concentration range of range 4.

The piezoelectric single crystal element may include a plurality of piezoelectric single crystals, and polymer layers may be disposed between the piezoelectric single crystals. Therefore, the piezoelectric single crystal element including a plurality of piezoelectric single crystals and polymer layers may constitute a piezoelectric single crystal composite. In this case, the polymer layers may have an arrangement structure that attenuates a negative piezoelectric strain constant corresponding to an arrangement direction or defines a vibration mode (extension mode) of each piezoelectric single crystal.

Hereinafter, examples of the present invention will be described.

### Example: Manufacture of Piezoelectric Single Crystal

A first solid-state reaction step was performed by mixing 13.4 mol or 11.0 mol of magnesium oxide, 19.0 mol or 18.6 mol of niobium oxide, 30.8 mol or 31.2 mol of titanium dioxide, 5.6 mol or 7.5 mol of indium oxide, and 0.05 mol of Mn to prepare a mixture, pulverizing and mixing the mixture using ethanol as a dispersion medium in a 0.5′ zirconia ball mill, drying the pulverized mixture in an electric furnace controlled at a temperature of 150 °C, and sintering the dried mixture in an alumina crucible with a lid at a temperature of 1600 °C for 6 hours. A second solid-state reaction step was performed by adding 31.1 mol or 31.5 mol of lead oxide to the product of the first solid-state reaction step, mixing them to prepare a mixture, pulverizing and mixing the mixture in the 0.5′ zirconia ball mill using ethanol as a dispersion medium, drying the mixture in the electric furnace controlled at a temperature of 150 °C, and sintering the dried mixture in the alumina crucible with a lid at a temperature of 900 °C for 4 hours.

The ceramic powder was put into a platinum crucible in which a seed with the crystal growth direction <011> had been charged, sealed, and placed in a high-temperature crystal growth furnace (1,500 °C, 100 psi) for 20 hours to be completely melted, maintained at a temperature of 1,500 °C for 360 hours, slowly cooled at a temperature of 20 °C to obtain a homogeneous piezoelectric single crystal with a diameter of 8 cm or more, and the crystal was processed into a wafer.

### Experimental Example: Physical Property Measurement

The piezoelectric single crystal obtained in the above-described example was cut into a 4×4×1 (mm) plate-shaped element in the <011> crystal orientation using a dicing saw, both surfaces of the single crystal were polished using a grinder and a lapping machine and washed using an ultrasonic cleaner, and then chromium and gold electrodes were formed on both surfaces using a DC magnetron sputterer (Model KVSC T5050).

In addition, in order to measure the piezoelectric properties, a DC electric field of 2 to 10 kV/cm was applied to the single crystal at a temperature of 120 °C for 30 minutes to polarize the single crystal, capacitance and dissipation measured at 1 kHz and 0.5 Vrms using an HP 4194A LF impedance analyzer (Hewlett-Packard Company, USA) were used to calculate a dielectric constant and dielectric loss of the single crystal, and an electromechanical coupling factor k₃₃, a piezoelectric strain constant d₃₃, a piezoelectric voltage constant g₃₃, and a mechanical quality factor Qₘ of a vibration mode in the polarization direction were calculated using resonance and antiresonance methods. In addition, the first FoM under non-resonant conditions, the second FoM under resonant conditions, and the third FoM in consideration of both non-resonant and resonant conditions were calculated. In addition, for Mn doping concentrations of 0 mol % and 1.5 mol %, an open-circuit voltage and a short-circuit current of the energy harvesting device were measured in an AC magnetic field of 7 Oe during a secondary bending mode operation and a root mean square (RMS) power value was measured. The piezoelectric single crystal is Mn:0.24PIN-0.48PMN-0.28PT (Mn doping concentration: 0 mol % to 0.9 mol %).

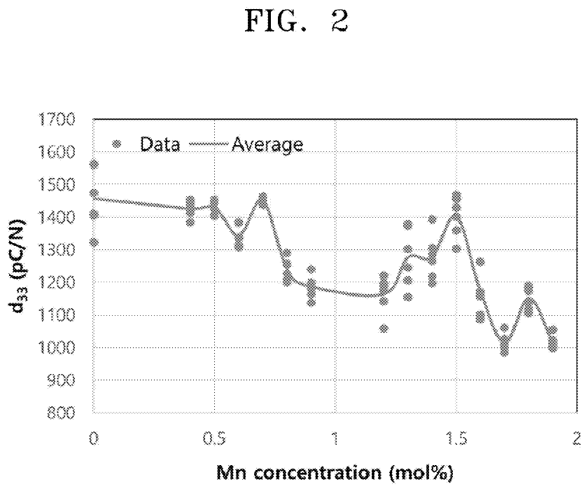

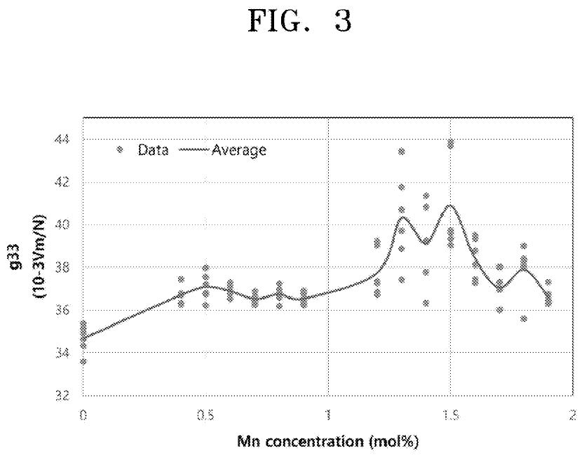

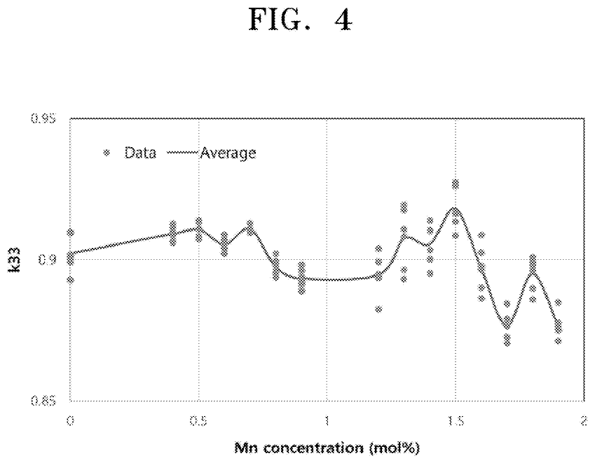

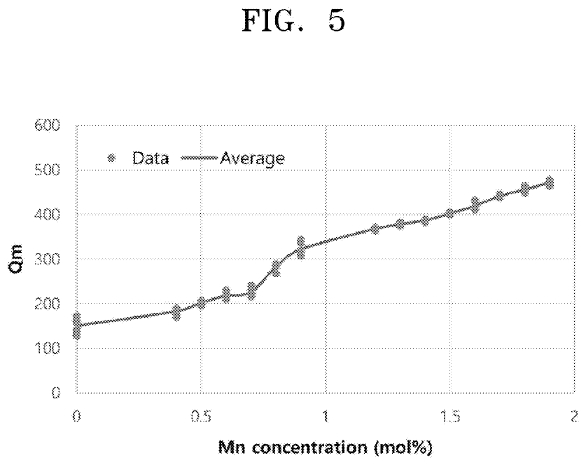

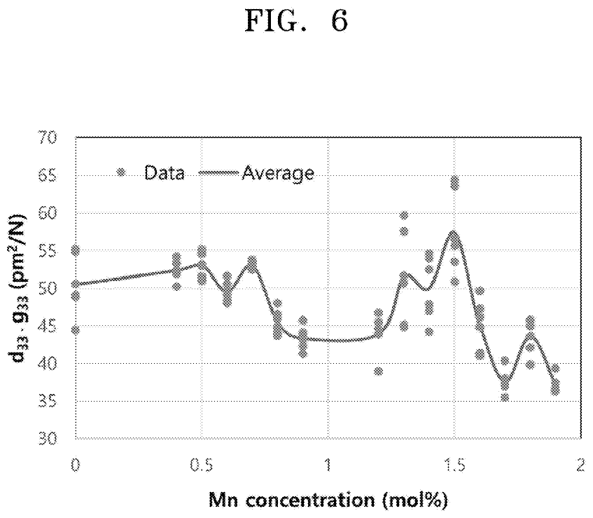

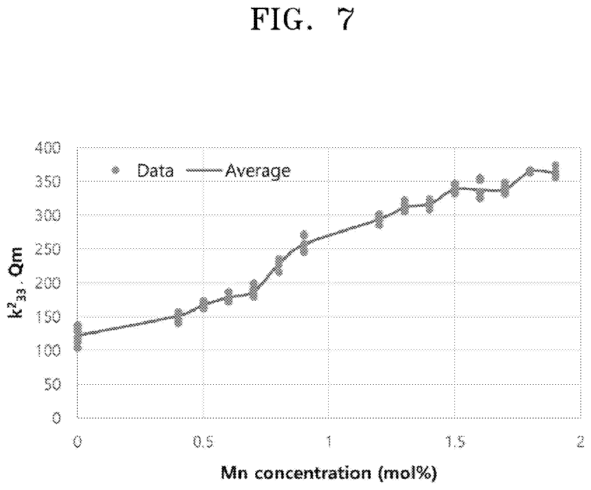

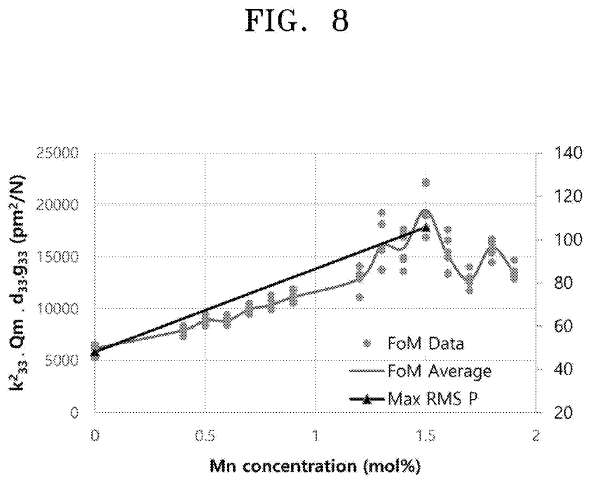

The physical properties (k₃₃, d₃₃, g₃₃, Qₘ, first to third FoMs) of multiple samples of the piezoelectric single crystals were measured at the same Mn doping concentration. Table 1 below shows average values of the physical property data of the multiple samples of piezoelectric single crystals, and FIGS. 2 to 8 show graphs that fit the physical property data of the multiple samples of piezoelectric single crystals on the basis of the average values (in FIGS. 2 to 8, Data means the physical property data of each sample, and Average means a fitting line that fits the physical property data of the plurality of samples based on the average values).

TABLE 1

| Average | | | | | | | | |
|---|---|---|---|---|---|---|---|---|
| | | | g₃₃ | | First FoM | Second | Third FoM | |
| Mn | | d₃₃ | (10⁻³ | | d₃₃*g₃₃ | FoM | d₃₃*g₃₃*Qm*k²₃₃ | |
| (mol %) | k₃₃ | (pC/N) | Vm/N) | Qₘ | (pm²/N) | Q*k²₃₃ | (pm²/N) | Note |
| 0 | 0.90 | 1456.02 | 34.67 | 150.21 | 50.52 | 122.16 | 6171.39 | Comparative Example |
| 0.4 | 0.91 | 1426.70 | 36.71 | 183.06 | 52.38 | 151.34 | 7926.46 | Comparative Example |
| 0.5 | 0.91 | 1430.89 | 37.08 | 201.76 | 53.06 | 167.37 | 8880.90 | Experimental |
| | | | | | | | | Example |
| | | | | | | | | (First FoM |
| | | | | | | | | local peak) |
| 0.6 | 0.91 | 1343.81 | 36.88 | 217.65 | 49.56 | 178.42 | 8843.26 | Comparative Example |
| 0.7 | 0.91 | 1450.64 | 36.52 | 225.50 | 52.97 | 187.12 | 9912.70 | Experimental |
| | | | | | | | | Example |
| | | | | | | | | (First FoM |
| | | | | | | | | local peak) |
| 0.8 | 0.90 | 1239.34 | 36.73 | 282.52 | 45.53 | 227.53 | 10359.59 | Comparative Example |
| 0.9 | 0.89 | 1186.61 | 36.53 | 321.52 | 43.36 | 256.63 | 11127.20 | Comparative Example |
| 1.2 | 0.89 | 1164.40 | 37.73 | 367.47 | 43.94 | 294.18 | 12927.46 | Comparative Example |
| 1.3 | 0.91 | 1276.60 | 40.31 | 377.85 | 51.59 | 311.25 | 16057.89 | Comparative Example |
| 1.4 | 0.91 | 1277.48 | 39.11 | 386.42 | 50.01 | 316.89 | 15847.50 | Comparative Example |
| 1.5 | 0.92 | 1402.48 | 40.88 | 401.78 | 57.43 | 338.69 | 19449.50 | Experimental |
| | | | | | | | | Example |
| | | | | | | | | (First FoM |
| | | | | | | | | local peak) |
| 1.6 | 0.90 | 1173.39 | 38.40 | 419.24 | 45.07 | 337.43 | 15208.87 | Comparative Example |
| 1.7 | 0.88 | 1014.18 | 37.05 | 440.92 | 37.58 | 338.83 | 12734.31 | Comparative Example |
| 1.8 | 0.90 | 1151.49 | 37.89 | 455.29 | 43.65 | 364.70 | 15919.84 | Experimental |
| | | | | | | | | Example |
| | | | | | | | | (Second FoM |
| | | | | | | | | local peak) |
| 1.9 | 0.88 | 1017.46 | 36.60 | 471.04 | 37.24 | 362.02 | 13482.27 | Comparative Example |

Table 1 shows that the first FoM of the piezoelectric single crystal has a local peak at the Mn doping concentrations of 0.5 mol %, 0.7 mol %, and 1.5 mol %, and the second FoM of the piezoelectric single crystal has a local peak at the Mn doping concentration of 1.8 mol %. In addition, an RMS power value of the energy harvesting device to which the piezoelectric single crystal having a Mn doping concentration of 0 mol % (i.e., the second-generation piezoelectric single crystal (PIN-PMN-PT)) was applied was measured to be 48.1 mW, and an RMS power value of the energy harvesting device to which the piezoelectric single crystal having a Mn doping concentration of 1.5 mol % (i.e., the third-generation piezoelectric single crystal (Mn:PIN-PMN-PT)) was applied was measured to be 105.8 mW. This means that when the volume of the energy harvesting device is the same, power density or energy density can be improved compared to the second-generation piezoelectric single crystal when the energy harvesting device is manufactured using the third-generation piezoelectric single crystal.

The following Table 2 shows the physical properties of the plurality of samples measured at Mn doping concentrations of 0.5 mol %, 0.7 mol % and 1.5 mol % at which the first FoM (FoM under non-resonant conditions) has a local peak.

TABLE 2

| | | | g₃₃ | | First FoM | |
|---|---|---|---|---|---|---|
| Mn | | d₃₃ | (10⁻³ | | d₃₃*g₃₃ | Range of |
| (mol %) | k₃₃ | (pC/N) | Vm/N) | Qₘ | (pm²/N) | first FoM |
| 0.5 | 0.91 | 1444.47 | 36.79 | 195.52 | 53.14 | min 50.97~ |
| 0.5 | 0.91 | 1406.79 | 36.23 | 198.29 | 50.97 | max 55.17 |
| 0.5 | 0.91 | 1453.91 | 37.54 | 199.20 | 54.58 | |
| 0.5 | 0.91 | 1403.29 | 36.73 | 204.23 | 51.55 | |
| 0.5 | 0.91 | 1452.85 | 37.97 | 206.30 | 55.17 | |
| 0.5 | 0.91 | 1424.05 | 37.19 | 207.01 | 52.96 | |
| 0.7 | 0.91 | 1464.00 | 36.42 | 216.42 | 53.32 | min 52.48~ |
| 0.7 | 0.91 | 1448.47 | 36.23 | 218.02 | 52.48 | max 53.72 |
| 0.7 | 0.91 | 1454.05 | 36.37 | 221.53 | 52.89 | |
| 0.7 | 0.91 | 1457.13 | 36.87 | 226.07 | 53.72 | |
| 0.7 | 0.91 | 1442.34 | 36.63 | 230.18 | 52.83 | |
| 0.7 | 0.91 | 1437.85 | 36.59 | 240.79 | 52.61 | |
| 1.5 | 0.92 | 1428.83 | 39.61 | 398.59 | 56.59 | min 50.87~ |
| 1.5 | 0.91 | 1360.11 | 39.34 | 399.66 | 53.50 | max 64.37 |
| 1.5 | 0.93 | 1467.40 | 43.87 | 400.70 | 64.37 | |
| 1.5 | 0.91 | 1303.01 | 39.04 | 402.12 | 50.87 | |
| 1.5 | 0.93 | 1454.85 | 43.69 | 404.74 | 63.56 | |
| 1.5 | 0.92 | 1400.68 | 39.74 | 404.84 | 55.66 | |

The following Table 3 shows the physical properties of the plurality of samples measured at a Mn doping concentration of 1.8 mol % at which the first FoM (FoM under resonant conditions) has a local peak.

TABLE 3

| | | | g₃₃ | | | |
|---|---|---|---|---|---|---|
| Mn | | d₃₃ | (10⁻³ | | Second FoM | Range of |
| (mol %) | k₃₃ | (pC/N) | Vm/N) | Qₘ | Q*k²₃₃ | second FoM |
| 1.8 | 0.90 | 1189.26 | 38.39 | 448.77 | 364.14 | min 363.15~ |
| 1.8 | 0.90 | 1139.90 | 38.28 | 450.24 | 363.15 | max 366.65 |
| 1.8 | 0.90 | 1183.09 | 38.01 | 450.98 | 364.87 | |
| 1.8 | 0.90 | 1172.99 | 39.00 | 455.39 | 365.83 | |
| 1.8 | 0.89 | 1105.35 | 38.08 | 463.09 | 366.65 | |
| 1.8 | 0.89 | 1118.33 | 35.59 | 463.25 | 363.54 | |

Meanwhile, as described above, the piezoelectric single crystal element may include a plurality of piezoelectric single crystals, and polymer layers may be disposed between the piezoelectric single crystals. Therefore, the piezoelectric single crystal element including a plurality of piezoelectric single crystals and polymer layers may constitute a piezoelectric single crystal composite. In this case, the polymer layers may have an arrangement structure that attenuates a negative piezoelectric strain constant corresponding to an arrangement direction or defines the vibration mode of each piezoelectric single crystal.

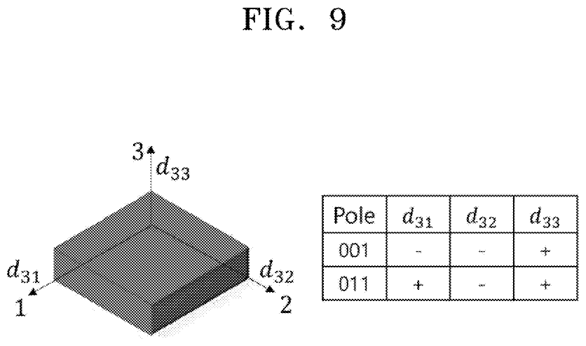

FIG. 9 is an exemplary diagram illustrating a relationship between a crystal orientation of the piezoelectric single crystal and the piezoelectric strain constant. The piezoelectric strain constant dᵢⱼ of the piezoelectric single crystal has different values and signs depending on the crystal orientation. For example, as shown in FIG. 9, when the crystal orientation is a <001> axis, d₃₁ and d₃₂ have negative values, and when the crystal orientation is a <011> axis, d₃₂ has a negative value.

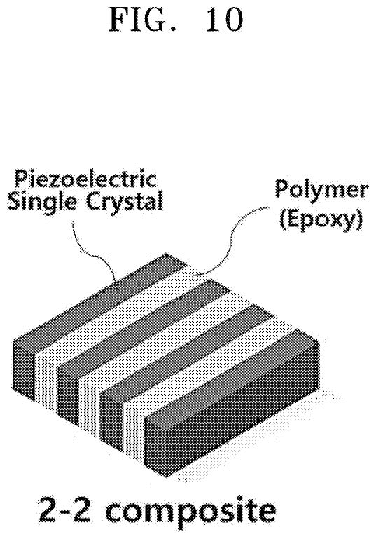

In the case of the piezoelectric single crystal element formed by bonding a plurality of piezoelectric single crystals through a polymer layer, the polymer layer may perform a function of attenuating the negative piezoelectric strain constant corresponding to the arrangement direction. For example, in the case of a piezoelectric single crystal having a <011> axis as a crystal orientation, since d₃₂ has a negative value, as shown in FIG. 10, when the piezoelectric single crystal element is implemented as a 2-2 composite, the polymer layer may function as an element that improves piezoelectric performance by attenuating d₃₂ having a negative value.

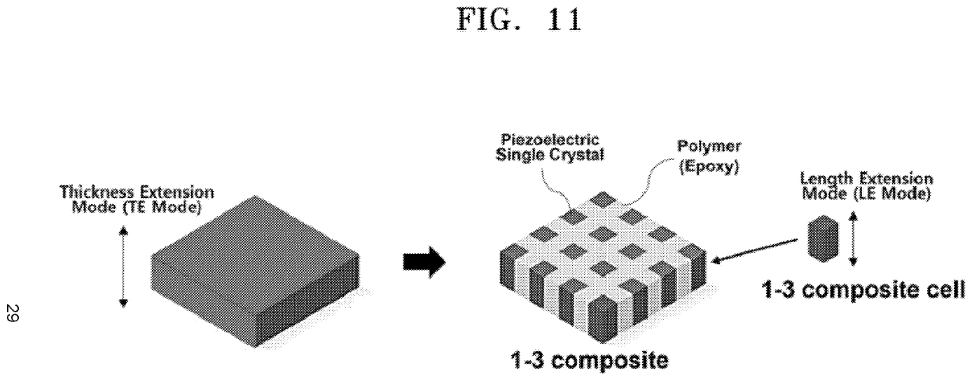

Meanwhile, the electromechanical coupling factor kₜ in a thickness direction of the piezoelectric single crystal is affected by the vibration mode of the piezoelectric single crystal. The vibration mode of a piezoelectric single crystal is determined by a ratio of its thickness, width, and length, and a thin planar piezoelectric single crystal operates in a thickness extension (TE) mode that vibrates in the thickness direction. When a piezoelectric single crystal element is implemented as a 1-3 composite, as shown in FIG. 11, since the width and length of each piezoelectric single crystal (single crystal cell) decreases relative to its thickness according to an arrangement structure of the polymer layers, each piezoelectric single crystal may operate in a length extension (LE) mode. That is, the polymer layer may have an arrangement structure for improving electromechanical coupling efficiency by defining the vibration mode of each piezoelectric single crystal, and the specific arrangement structure (i.e., the composite structure of the piezoelectric single crystal element) may be determined according to the type and specifications of a dielectric device to be manufactured.

According to the present invention, the energy density and energy conversion efficiency of various dielectric devices (e.g., energy harvesting devices) utilizing a piezoelectric single crystal can be improved.

However, the effects obtainable through the present invention are not limited to the above effects, and other technical effects that are not described herein will be clearly understood by those skilled in the art from the above description of the present invention.

While the present invention has been described with reference to embodiments shown in the drawings, these embodiments are merely illustrative and it should be understood that various modifications and equivalent other embodiments can be derived by those skilled in the art on the basis of the embodiments. Therefore, the true technical scope of the present invention should be defined by the appended claims.

This research was conducted with the support of the Defense Innovation Enterprise 100 Project R & D Support Project of the Korea Research Institute for Defense Technology Planning and Advancement funded by the Defense Acquisition Program Administration (R230102).

What is claimed is:

1. A piezoelectric single crystal element comprising one or more piezoelectric single crystals, wherein the one or more piezoelectric single crystals include:
a solid solution with a chemical formula yPb(In_{1/2}Nb_{1/2})O₃-xPbTiO₃-(1−x−y)Pb(Mg_{1/3}Nb_{2/3})O₃, wherein x is greater than 0 to 0.54 or greater than 0 to 0.5, and y is greater than 0 to 0.4 or greater than 0 to 0.3; and
manganese (Mn) doped into the solid solution at a concentration of 0.45 to 0.55 mol %, 0.65 to 0.75 mol %, 1.45 to 1.55 mol %, or 1.75 to 1.85 mol %, and
have a piezoelectric strain constant (d33) of 1150 to 1470 pC/N.

2. The piezoelectric single crystal element of claim 1, wherein a figure of merit (FoM) of the piezoelectric single crystals has a peak in a Mn doping concentration range of 0.45 to 0.55 mol %, 0.65 to 0.75 mol %, 1.45 to 1.55 mol %, or 1.75 to 1.85 mol %.

3. The piezoelectric single crystal element of claim 2, wherein a first FoM of the piezoelectric single crystals, which is defined according to a piezoelectric strain constant (d₃₃) and a piezoelectric voltage constant (g₃₃) of the piezoelectric single crystals, has a peak in a Mn doping concentration range of 0.45 to 0.55 mol %, 0.65 to 0.75 mol %, or 1.45 to 1.55 mol %.

4. The piezoelectric single crystal element of claim 3, wherein the peak of the first FoM has a value between 50 and 56 pm²/N, a value between 52 and 54 pm²/N, or a value between 50 and 65 pm²/N in the Mn doping concentration range of 0.45 to 0.55 mol %, 0.65 to 0.75 mol %, or 1.45 to 1.55 mol %.

5. The piezoelectric single crystal element of claim 2, wherein a second FoM of the piezoelectric single crystals, which is defined according to an electromechanical coupling factor (k₃₃) and a mechanical quality factor (Qₘ) of the piezoelectric single crystals, has a peak in a Mn doping concentration range of 1.75 to 1.85 mol %.

6. The piezoelectric single crystal element of claim 5, wherein the peak of the second FoM has a value between 363 and 367 in the Mn doping concentration range of 1.75 to 1.85 mol %.

7. The piezoelectric single crystal element of claim 1, wherein a crystal orientation of the piezoelectric single crystals is a <011> axis.

8. The piezoelectric single crystal element of claim 1, wherein:
the piezoelectric single crystals are provided as a plurality of piezoelectric single crystals, and polymer layers are disposed between the piezoelectric single crystals such that the piezoelectric single crystal element constitutes a piezoelectric single crystal composite; and
the polymer layers have an arrangement structure that attenuates a negative piezoelectric strain constant corresponding to an arrangement direction thereof or defines a vibration mode (extension mode) of each piezoelectric single crystal.
